(19) United States
(12) Patent Application Publication
(10) Pub. No.: US 2026/0045305 A1
(43) Pub. Date: Feb. 12, 2026

(54) SEMICONDUCTOR MEMORY DEVICE

(71) Applicant: SK hynix Inc., Gyeonggi-do (KR)

(72) Inventors: Yun Su KIM, Gyeonggi-do (KR); Han Soo JOO, Gyeonggi-do (KR); Da Won KIM, Gyeonggi-do (KR)

(21) Appl. No.: 19/057,799

(22) Filed: Feb. 19, 2025

(30) Foreign Application Priority Data
Aug. 8, 2024 (KR) 10-2024-0106084

(51) Int. Cl. G11C 16/10; G11C 5/06; G11C 16/04; G11C 16/08

(52) U.S. Cl. CPC G11C 16/107; G11C 5/063; G11C 16/0483; G11C 16/08

(57) ABSTRACT

Provided herein is a semiconductor memory device. The semiconductor memory device may include a memory block including a plurality of pages, a peripheral circuit configured to perform a program operation on the memory block by respectively applying a program voltage, a pass voltage, and a calibration pass voltage to a plurality of word lines respectively connected to the plurality of pages, and a control logic configured to control the peripheral circuit to vary a potential of the calibration pass voltage to be applied to a lowermost word line connected to a page adjacent to a semiconductor substrate or a source select transistor among the plurality of pages based on a position of a page selected from among the plurality of pages during the program operation.

### CROSS-REFERENCE TO RELATED APPLICATION

The present application claims priority under 35 U.S.C. § 119(a) to Korean patent application number 10-2024-0106084 filed on Aug. 8, 2024, the entire disclosure of which is incorporated by reference herein.

### BACKGROUND

### 1. Field of Invention

Various embodiments of the present disclosure relate to an electronic device, and more particularly to a semiconductor memory device that is capable of storing data.

### 2. Description of Related Art

Semiconductor devices, especially semiconductor memory devices, are broadly classified into volatile memory devices and nonvolatile memory devices.

The nonvolatile memory device has relatively low write and read speeds, but retains data stored therein even when power supply is interrupted. Therefore, the nonvolatile memory device is used to store data to be retained regardless of whether power is supplied. Representative examples of the nonvolatile memory device include a read-only memory (ROM), a mask ROM (MROM), a programmable ROM (PROM), an erasable programmable ROM (EPROM), an electrically erasable programmable ROM (EEPROM), a flash memory, a phase-change random access memory (PRAM), a magnetic RAM (MRAM), a resistive RAM (RRAM), a ferroelectric RAM (FRAM), etc. The flash memory is classified into a NOR type and a NAND type.

The flash memory has the advantage of RAM in which data is freely programmable and erasable, and the advantage of ROM in which stored data can be retained even when power supply is interrupted. Thus, a flash memory is widely used as the storage medium of portable electronic devices such as a digital camera, a personal digital assistant (PDA), and an MP3 player.

The flash memory device may be classified into a two-dimensional (2D) semiconductor device in which memory cell strings are horizontally formed on a semiconductor substrate, and a three-dimensional (3D) semiconductor device in which memory cell strings are vertically formed on a semiconductor substrate.

As the 2D semiconductor device is reaching its physical scaling limit (i.e., limit in the degree of integration), the 3D semiconductor device including a plurality of memory cell strings vertically formed on a semiconductor substrate is produced. Each of the memory cell strings includes a drain select transistor, memory cells, and a source select transistor, which are connected in series between a bit line and a source line.

### SUMMARY

Various embodiments of the present disclosure are directed to a semiconductor memory device that is capable of mitigating a program disturb phenomenon during a program operation of the semiconductor memory device.

An embodiment of the present disclosure may provide for a semiconductor memory device. The semiconductor memory device may include a memory block including a plurality of pages, a peripheral circuit configured to perform a program operation on the memory block by respectively applying a program voltage, a pass voltage, and a calibration pass voltage to a plurality of word lines respectively connected to the plurality of pages, and a control logic configured to control the peripheral circuit to vary a potential of the calibration pass voltage to be applied to a lowermost word line connected to a page adjacent to a semiconductor substrate or a source select transistor among the plurality of pages based on a position of a page selected from among the plurality of pages during the program operation.

An embodiment of the present disclosure may provide for a semiconductor memory device. The semiconductor memory device may include a memory block connected to a plurality of word lines grouped into a plurality of word line groups, a voltage generator configured to generate a program voltage, a pass voltage, and a calibration pass voltage having a potential lower than or equal to a potential of the pass voltage during a program operation on the memory block, an address decoder configured to apply the program voltage to a selected word line among the plurality of word lines, apply the calibration pass voltage to a lowermost word line connected to memory cells adjacent to a semiconductor substrate or a source select transistor among the plurality of word lines, and apply the pass voltage to remaining unselected word lines, other than the selected word line and the lowermost word line, among the plurality of word lines, during the program operation, and a control logic configured to control the voltage generator and the address decoder to perform the program operation, and control the voltage generator to vary the potential of the calibration pass voltage based on a word line group corresponding to the selected word line during the program operation.

An embodiment of the present disclosure may provide for a semiconductor memory device. The semiconductor memory device may include a memory block including memory cells connected to a plurality of word lines, a peripheral circuit configured to apply a program voltage to a selected word line among the plurality of word lines and apply a pass voltage and a calibration pass voltage to unselected word lines during a program operation on the memory block, and a control logic configured to control the peripheral circuit to vary a potential of the calibration pass voltage to be applied to one of the unselected word lines based on a position of the selected word line during the program operation, wherein the potential of the calibration pass voltage sequentially decreases as a distance between the selected word line and the unselected word line to which the calibration pass voltage is applied becomes greater.

### BRIEF DESCRIPTION OF THE DRAWINGS

FIG. 1 is a block diagram illustrating a semiconductor memory device according to an embodiment of the present disclosure.

FIG. 2 is a block diagram illustrating an embodiment of a memory cell array of FIG. 1.

FIG. 3 is a perspective view illustrating a memory cell string included in a memory block according to an embodiment of the present disclosure.

FIGS. 4 and 5 are circuit diagrams illustrating a memory block according to an embodiment of the present disclosure.

FIG. 6 is a block diagram illustrating a control logic of FIG. 1.

FIG. 7 is a block diagram illustrating a voltage generator of FIG. 1.

FIG. 8 is a flowchart illustrating a method of performing a program operation of a semiconductor memory device according to an embodiment of the present disclosure.

FIG. 9 is a diagram for describing a calibration pass voltage applied to the lowermost word line during a program operation on memory cells corresponding to a plurality of word line groups according to an embodiment of the present disclosure.

FIG. 10 is a diagram for describing voltages applied to word lines during a program operation of a semiconductor memory device according to an embodiment of the present disclosure.

FIG. 11 is a block diagram illustrating a memory system including the semiconductor memory device of FIG. 1 according to an embodiment of the present disclosure.

FIG. 12 is a block diagram illustrating an application of the memory system of FIG. 11 according to an embodiment of the present disclosure.

FIG. 13 is a block diagram illustrating a computing system including the memory system illustrated with reference to FIG. 12 according to an embodiment of the present disclosure.

### DETAILED DESCRIPTION

Advantages and features of the embodiments of the present disclosure, and methods for achieving the same will be shown with reference to embodiments described in detail together with the accompanying drawings. However, the embodiments of the present disclosure are not limited to the following embodiments, but may be embodied in other forms. Various embodiments of the present disclosure are provided in detail so that those skilled in the art to which the present disclosure pertains can easily practice the technical concepts of the present disclosure.

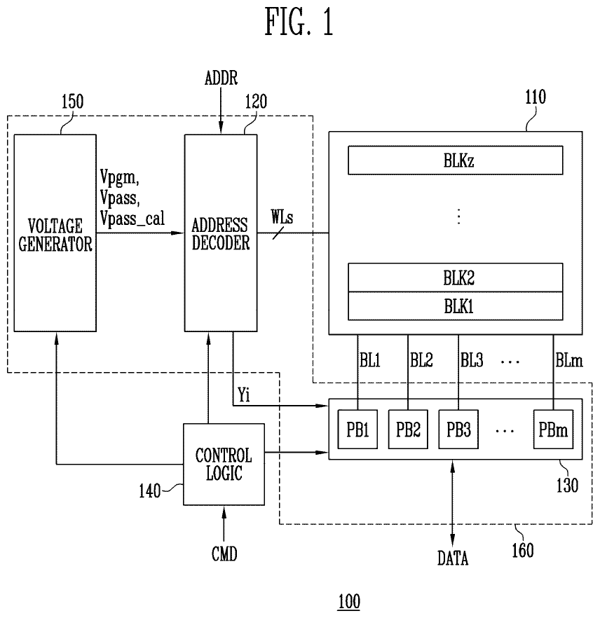

FIG. 1 is a block diagram illustrating a semiconductor memory device according to an embodiment of the present disclosure.

Referring to FIG. 1, a semiconductor memory device 100 includes a memory cell array 110, an address decoder 120, a read and write circuit 130, a control logic 140, and a voltage generator 150.

The memory cell array 110 includes a plurality of memory blocks BLK1 to BLKz. The plurality of memory blocks BLK1 to BLKz may be connected to the address decoder 120 through word lines WLs. The plurality of memory blocks BLK1 to BLKz are connected to the read and write circuit 130 through bit lines BL1 to BLm. Each of the memory blocks BLK1 to BLKz may include a plurality of memory cells. In an embodiment, the plurality of memory cells may be nonvolatile memory cells. Memory cells connected to one word line among the plurality of memory cells may be defined as one page. The memory cell array 110 may be composed of a plurality of pages.

In addition, each of the memory blocks BLK1 to BLKz of the memory cell array 110 includes a plurality of memory cell strings. Each of the memory cell strings includes a drain select transistor, a plurality of memory cells, and a source select transistor, which are connected in series between a corresponding bit line and a source line. The plurality of memory cells may be connected to a plurality of word lines, respectively. Among the plurality of memory cells, a word line connected to a lowermost memory cell adjacent to the source select transistor may be defined as the lowermost word line. In an embodiment, word lines connected to at least two lowermost memory cells adjacent to the source select transistor among the plurality of memory cells may be defined as the lowermost word lines. Detailed description of the memory cell array 110 will be made later.

The address decoder 120, the read and write circuit 130, and the voltage generator 150 are operated as a peripheral circuit 160 which drives the memory cell array 110.

The address decoder 120 may be connected to the memory cell array 110 through the word lines WLs. The address decoder 120 may be operated under the control of the control logic 140. The address decoder 120 receives addresses ADDR through an input/output buffer (not illustrated) provided in the semiconductor memory device 100.

The address decoder 120 may transfer a program voltage Vpgm, a pass voltage Vpass, a calibration pass voltage Vpass_cal, which are generated by the voltage generator 150, to the word lines WLs of the memory cell array 110 according to the received addresses ADDR during a read operation.

For example, the address decoder 120 may apply the program voltage Vpgm to a selected or target word line among the word lines WLs, apply a calibration pass voltage Vpass_cal to the lowermost word line adjacent to the source line among unselected or non-target word lines, and apply the pass voltage Vpass to the remaining unselected or non-target word lines during a program operation. The calibration pass voltage Vpass_cal may have a potential lower than or equal to that of the pass voltage Vpass.

The address decoder 120 may decode a column address among the received addresses ADDR. The address decoder 120 transmits a decoded column address Yi to the read and write circuit 130.

The addresses ADDR received in the program operation include a block address, a row address, and a column address. The address decoder 120 may select one memory block and one word line according to the block address and the row address. The column address Yi is decoded by the address decoder 120 and provided to the read and write circuit 130.

The address decoder 120 may include a block decoder, a row decoder, a column decoder, an address buffer, etc.

The read and write circuit 130 may include a plurality of page buffers PB1 to PBm. The plurality of page buffers PB1 to PBm are connected to the memory cell array 110 through the bit lines BL1 to BLm. Each of the plurality of page buffers PB1 to PBm may store data to be programmed in the program operation, and may apply a program-enable voltage (e.g., 0 V) or a program-inhibit voltage (e.g., supply voltage) to corresponding bit lines BL1 to BLm based on the stored data.

The read and write circuit 130 may be operated under the control of the control logic 140.

In an embodiment, the read and write circuit 130 may include page buffers (or page registers), a column select circuit, etc.

The control logic 140 may be connected to the address decoder 120, the read and write circuit 130, and the voltage generator 150. The control logic 140 may receive a command CMD through an input/output buffer (not shown) of the semiconductor memory device 100. The control logic 140 may control the program operation of the semiconductor memory device 100 in response to the command CMD.

The control logic 140 may control the address decoder 120, the read and write circuit 130, and the voltage generator 150 to perform a program operation on a plurality of memory cells included in a selected or target page during the program operation. Further, the control logic 140 may control the voltage generator 150 to generate the calibration pass voltage Vpass_cal that is applied to the lowermost word line by varying the potential of the calibration pass voltage Vpass_cal depending on the physical position of the selected or target page or the selected or target word line during the program operation.

For example, when the selected or target page is located in an upper portion of the memory cell string, the control logic 140 may control the voltage generator 150 to generate the calibration pass voltage Vpass_cal having a relatively low potential, whereas when the selected or target page is located in a lower portion of the memory cell string, the control logic 140 may control the voltage generator 150 to generate the calibration pass voltage Vpass_cal having a relatively high potential.

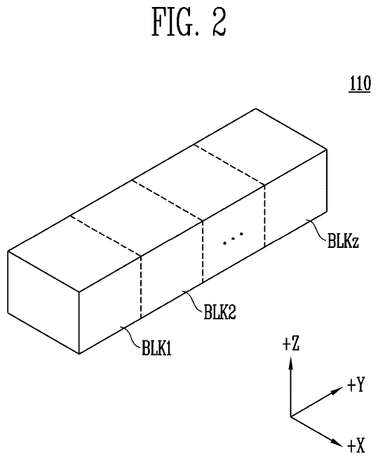

FIG. 2 is a block diagram illustrating an embodiment of the memory cell array of FIG. 1.

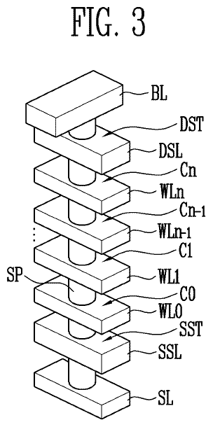

Referring to FIG. 2, the memory cell array 110 includes a plurality of memory blocks BLK1 to BLKz. Each memory block has a three-dimensional (3D) structure. Each memory block includes a plurality of memory cells stacked on a substrate. The plurality of memory cells are arranged in +X, +Y, and +Z directions. The structure of each memory block will be described in detail below with reference to FIGS. 3, 4, and 5.

FIG. 3 is a perspective view illustrating a memory cell string included in a memory block according to an embodiment of the present disclosure.

Referring to FIG. 3, a source line SL may be formed on a semiconductor substrate. A vertical channel layer SP may be formed on the source line SL. An upper portion of the vertical channel layer SP is coupled to a bit line BL. The vertical channel layer SP may be formed of polysilicon. A plurality of conductive layers SSL, WL0 to WLn, and DSL are formed to enclose the vertical channel layer SP at different heights of the vertical channel layer SP. Multi-layers (not illustrated) including a charge storage layer are formed on a surface of the vertical channel layer SP. The multi-layers are also disposed between the vertical channel layer SP and the conductive layers SSL, WL0 to WLn, and DSL. The multi-layers may be formed in an ONO structure in which an oxide layer, a nitride layer, and an oxide layer are sequentially stacked.

The lowermost conductive layer forms a source select line SSL, and the uppermost conductive layer forms a drain select line DSL. The conductive layers disposed between the select lines SSL and DSL may form the respective word lines WL0 to WLn. The conductive layers SSL, WL0 to WLn, and DSL are formed in a multi-layer structure on the semiconductor substrate. The vertical channel layer SP passing through the conductive layers SSL, WL0 to WLn, and DSL is vertically coupled between the bit line BL and the source line SL formed on the semiconductor substrate.

A drain select transistor DST is formed on a portion of the uppermost conductive layer DSL that encloses the vertical channel layer SP, and a source select transistor SST is formed on a portion of the lowermost conductive layer SSL that encloses the vertical channel layer SP. Memory cells MC0 to MCn are respectively formed on portions of the intermediate conductive layers WL0 to WLn that enclose the vertical channel layer SP.

In this way, the memory cell string includes the source select transistor SST, the memory cells C0 to Cn, and the drain select transistor DST, which are vertically coupled to the substrate between the source line SL and the bit line BL. The source select transistor SST electrically connects the memory cells C0 to Cn to the source line SL depending on a source control voltage applied to the source select line SSL. The drain select transistor DST electrically connects the memory cells C0 to Cn to the bit line BL depending on a drain control voltage applied to the drain select line DSL.

In an embodiment, in the process of manufacturing the memory cell string, the width of the vertical channel layer SP or a cross-sectional area parallel to the upper surface of the semiconductor substrate may be formed to be thinner as the distance from the semiconductor substrate decreases. For example, the memory cell C0 may be a memory cell closest to the semiconductor substrate, and the memory cell Cn may be a memory cell farthest from the semiconductor substrate. Therefore, when the same voltage is applied to the word lines WL0 to WLn connected to the memory cells C0 to Cn, an electric field formed in a memory cell (e.g., C0) adjacent to the semiconductor substrate or the source select transistor SST may be stronger than an electric field formed in other memory cells (e.g., C1 to Cn). This characteristic may cause a program disturb phenomenon while a program operation is performed.

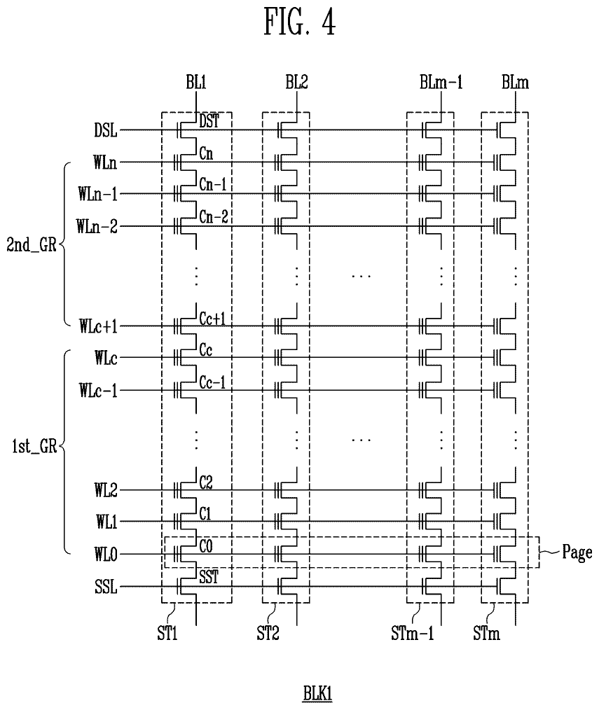

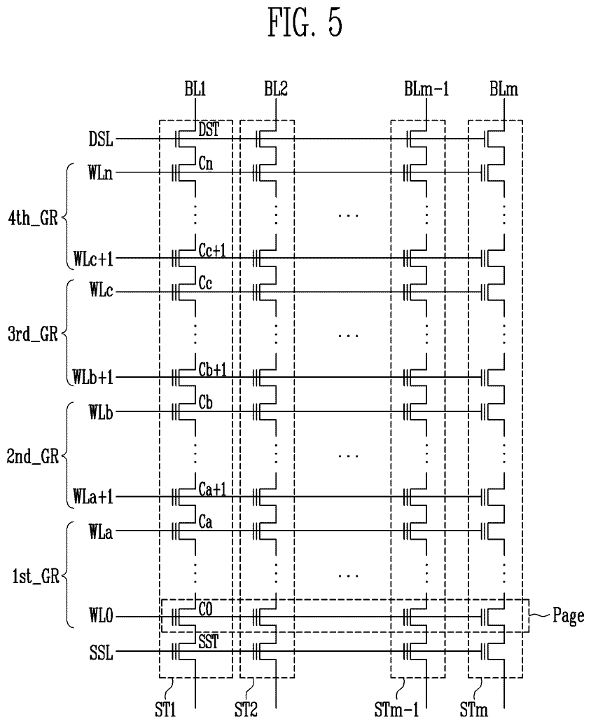

FIGS. 4 and 5 are circuit diagrams illustrating a memory block according to an embodiment of the present disclosure.

Referring to FIGS. 4 and 5, one memory block (e.g., BLK1) may be connected to a plurality of word lines arranged in parallel between a first select line and a second select line. Here, the first select line may be a source select line SSL, and the second select line may be a drain select line DSL. In detail, the memory block BLK1 may include a plurality of memory cell strings ST1 to STm connected between bit lines BL1 to BLm and a source line SL. The bit lines BL1 to BLm may be connected to the memory cell strings ST1 to STm, respectively, and the source line SL may be connected in common to the memory cell strings ST1 to STm. Since the memory cell strings ST1 to STm may be equally configured, the memory cell string ST1 connected to the first bit line BL1 will be described in detail by way of example.

The memory cell string ST1 may include a source select transistor SST, a plurality of memory cells C0 to Cn, and a drain select transistor DST which are connected in series to each other between the source line SL and the first bit line BL1. In the memory cell string ST1, at least one source select transistor SST and at least one drain select transistor DST may be included.

A source of the source select transistor SST may be connected to the source line SL, and a drain of the drain select transistor DST may be connected to the first bit line BL1. The plurality of memory cells C0 to Cn may be connected in series between the source select transistor SST and the drain select transistor DST. Gates of the source select transistors SST included in different memory cell strings may be connected to the source select line SSL, gates of the drain select transistors DST included in different memory cell strings ST may be connected to the drain select line DSL, and gates of the memory cells C0 to Cn may be connected to a plurality of word lines WL0 to WLn, respectively. A group of memory cells connected to the same word line, among the memory cells included in different memory cell strings ST1 to STm, may be referred to as a page. Therefore, the memory block BLK1 may include a number of pages identical to the number of word lines WL0 to WLn.

The plurality of word lines WL0 to WLn respectively corresponding to the plurality of pages may be grouped into a plurality of word line groups.

Referring to FIG. 4, the plurality of word lines WL0 to WLn may be grouped into two word line groups, that is, a first word line group 1st_GR and a second word line group 2nd_GR. The first word line group 1st_GR may include a plurality of word lines WL0 to WLc, and the second word line group 2nd_GR may include a plurality of word lines WLc+1 to WLn. The first word line group 1st_GR may correspond to pages corresponding to a lower portion of the memory cell string, and the second word line group 2nd_GR may correspond to pages corresponding to an upper portion of the memory cell string. The word line WL0 corresponding to at least one lowermost page closest to the semiconductor substrate or the source select transistor SST among the plurality of pages may be defined as the lowermost word line, and the lowermost word line may be included in the first word line group 1st_GR.

The plurality of pages may be grouped into a plurality of page groups, as in the case of the corresponding word lines WL0 to WLn. For example, pages connected to the plurality of word lines WL0 to WLc included in the first word line group 1st_GR may be defined as a first page group, and pages connected to the plurality of word lines WLc+1 to WLn included in the second word line group 2nd_GR may be defined as a second page group.

The plurality of memory cells C0 to Cn may be grouped into a plurality of memory cell groups as in the case of the corresponding word lines WL0 to WLn. For example, the plurality of memory cells C0 to Cc connected to the plurality of word lines WL0 to WLc included in the first word line group 1st_GR may be defined as a first memory cell group, and the plurality of memory cells Cc+1 to Cn connected to the plurality of word lines WLc+1 to WLn included in the second word line group 2nd_GR may be defined as a second memory cell group.

Referring to FIG. 5, the plurality of word lines WL0 to WLn may be grouped into four word line groups, that is, a first word line group 1st_GR, a second word line group 2nd_GR, a third word line group 3rd_GR, and a fourth word line group 4th_GR. The first word line group 1st_GR may include a plurality of word lines WL0 to WLa, and the second word line group 2nd_GR may include a plurality of word lines WLa+1 to WLb. The third word line group 3rd_GR may include a plurality of word lines WLb+1 to WLc, and the fourth word line group 4th_GR may include a plurality of word lines WLc+1 to WLn.

The first word line group 1st_GR, the second word line group 2nd_GR, the third word line group 3rd_GR, and the fourth word line group 4th_GR may be arranged to be sequentially stacked on a semiconductor substrate. Among the plurality of memory cells C0 to Cn included in the memory cell string, memory cells C0 to Ca closest to the semiconductor substrate or the source select transistor SST may correspond to the first word line group 1st_GR. Among the plurality of memory cells C0 to Cn included in the memory cell string, memory cells Ca+1 to Cb farther from the semiconductor substrate or the source select transistor SST than the memory cells C0 to Ca corresponding to the first word line group 1st_GR may correspond to the second word line group 2nd_GR. Among the plurality of memory cells C0 to Cn included in the memory cell string, memory cells Cb+1 to Cc farther from the semiconductor substrate or the source select transistor SST than the memory cells Ca+1 to Cb corresponding to the second word line group 2nd_GR may correspond to the third word line group 3rd_GR. Among the plurality of memory cells C0 to Cn included in the memory cell string, memory cells Cc+1 to Cn farther from the semiconductor substrate or the source select transistor SST than the memory cells Cb+1 to Cc corresponding to the third word line group 3rd_GR may correspond to the fourth word line group 4th_GR.

Although, in FIGS. 4 and 5, the embodiment in which the plurality of word lines WL0 to WLn respectively corresponding to a plurality of pages are grouped into two or four word line groups is described, the embodiments of the present disclosure are not limited thereto, and the plurality of word lines WL0 to WLn may be grouped to two or more word line groups.

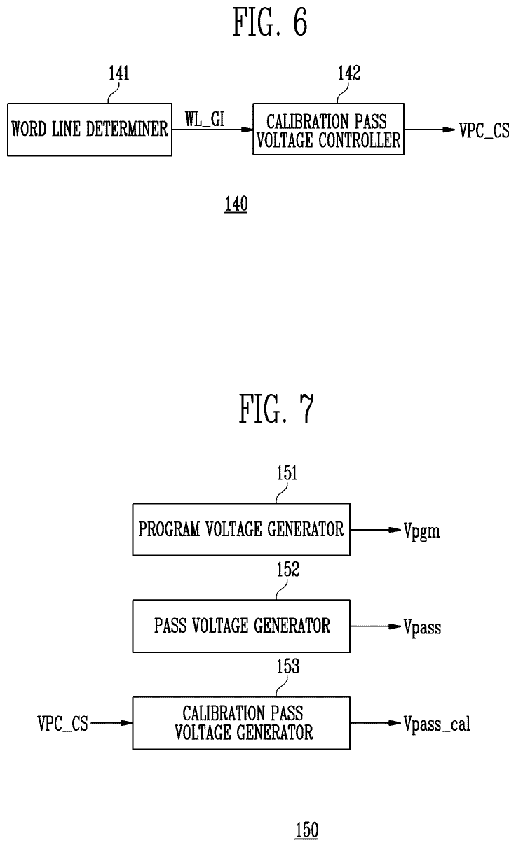

FIG. 6 is a block diagram illustrating the control logic of FIG. 1.

Referring to FIG. 6, the control logic 140 may include a word line determiner 141 and a calibration pass voltage controller 142.

During a program operation, the word line determiner 141 may determine a target word line group, in which a selected or target word line corresponding to a selected or target page is included among a plurality of word line groups, during a program operation and may output word line group information WL_GI corresponding to the selected or target page.

The calibration pass voltage controller 142 may receive the word line group information WL_GI from the word line determiner 141, set a calibration pass voltage level corresponding to the word line group information WL_GI, and output a calibration pass voltage generation control signal VPC_CS for controlling the voltage generator (e.g., 150 of FIG. 1) to generate a calibration pass voltage having the set calibration pass voltage level.

In an embodiment, the control logic 140 may allocate different calibration pass voltage levels to the respective word line groups of FIG. 4 or 5, and may control the voltage generator 150 of FIG. 1 to generate a calibration pass voltage having a calibration pass voltage level allocated to a word line group including a word line corresponding to a selected or target page during a program operation on the selected or target page.

In an embodiment, when the selected or target page is included in the first word line group 1st_GR of FIG. 5 during the program operation, the calibration pass voltage controller 142 may set the potential of the calibration pass voltage to a first calibration pass voltage level based on the word line group information WL_GI output from the word line determiner 141. Further, when the selected or target page is included in the second word line group 2nd_GR of FIG. 5 during the program operation, the calibration pass voltage controller 142 may set the potential of the calibration pass voltage to a second calibration pass voltage level lower than the first calibration pass voltage level based on the word line group information WL_GI output from the word line determiner 141. Further, when the selected or target page is included in the third word line group 3rd_GR of FIG. 5 during the program operation, the calibration pass voltage controller 142 may set the potential of the calibration pass voltage to a third calibration pass voltage level lower than the second calibration pass voltage level based on the word line group information WL_GI output from the word line determiner 141. Further, when the selected or target page is included in the fourth word line group 4th_GR of FIG. 5 during the program operation, the calibration pass voltage controller 142 may set the potential of the calibration pass voltage to a fourth calibration pass voltage level lower than the third calibration pass voltage level based on the word line group information WL_GI output from the word line determiner 141.

FIG. 7 is a block diagram illustrating the voltage generator of FIG. 1.

Referring to FIG. 7, the voltage generator 150 may include a program voltage generator 151, a pass voltage generator 152, and a calibration pass voltage generator 153.

The program voltage generator 151 may generate and output a program voltage Vpgm to be applied to a selected or target word line during a program operation.

The pass voltage generator 152 may generate and output a pass voltage Vpass to be applied to unselected or non-target word lines during the program operation.

The calibration pass voltage generator 153 may generate and output a calibration pass voltage Vpass_cal to be applied to the lowermost word line among the unselected or non-target word lines during the program operation. When the selected or target word line is the lowermost word line during the program operation, the calibration pass voltage generator 153 may be disabled.

The calibration pass voltage generator 153 may output the calibration pass voltage Vpass_cal by calibrating the potential level of the calibration pass voltage Vpass_cal in response to the calibration pass voltage generation control signal VPC_CS generated by the calibration pass voltage controller 142 of FIG. 6. For example, the calibration pass voltage generator 153 may generate and output the calibration pass voltage Vpass_cal having the potential level set by the calibration pass voltage controller 142 in response to the calibration pass voltage generation control signal VPC_CS.

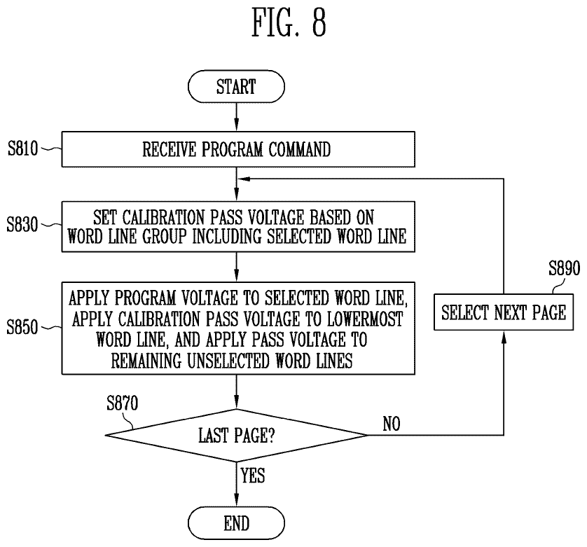

FIG. 8 is a flowchart illustrating a method of performing a program operation of a semiconductor memory device according to an embodiment of the present disclosure.

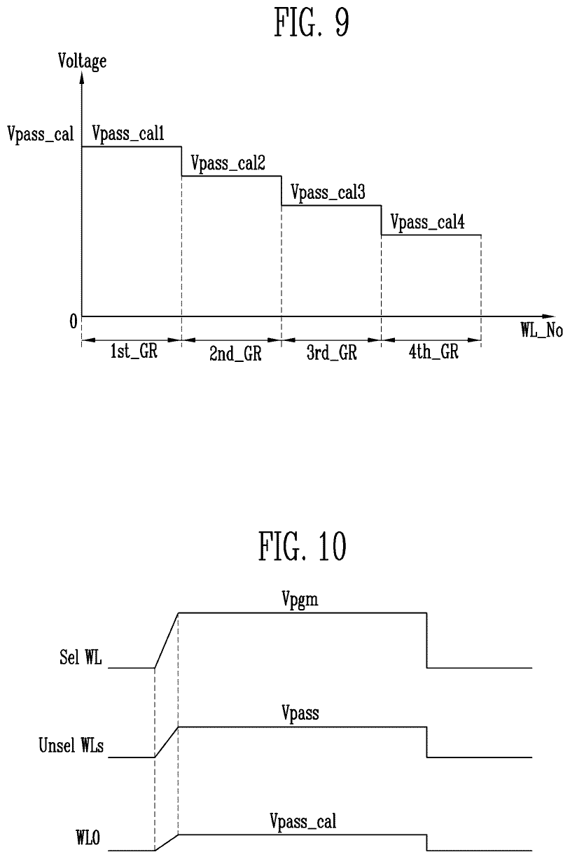

FIG. 9 is a diagram for describing a calibration pass voltage applied to the lowermost word line during a program operation on memory cells corresponding to a plurality of word line groups according to an embodiment of the present disclosure.

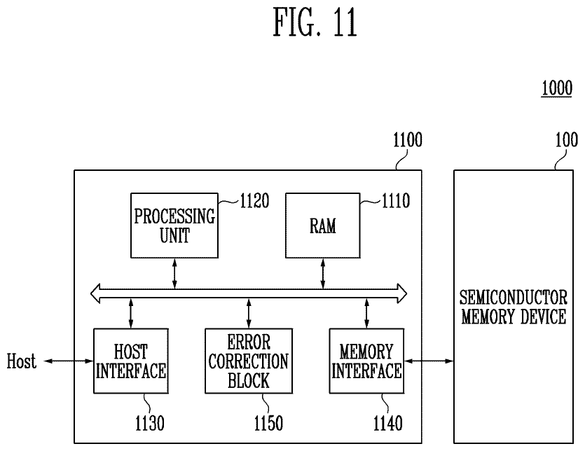

FIG. 10 is a diagram for describing voltages applied to word lines during a program operation of a semiconductor memory device according to an embodiment of the present disclosure.

The program operation of the semiconductor memory device according to the embodiment of the present disclosure will be described below with reference to FIGS. 1, 3, and 5 to 10.

At operation S810, the semiconductor memory device 100 receives a command CMD corresponding to a program operation and an address ADDR corresponding to memory cells on which the program operation is to be performed, from an external device, for example, a controller which controls the semiconductor memory device 100. Further, the semiconductor memory device 100 may also receive data DATA to be programmed from the external device.

At operation S830, the control logic 140 may determine a target word line group including a selected or target word line corresponding to a selected or target page and set the potential of a calibration pass voltage based on the determined word line group during the program operation.

In an embodiment, during a program operation, the word line determiner 141 may determine a word line group, in which a selected or target word line corresponding to a selected or target page is included among a plurality of word line groups, and may output word line group information WL_GI corresponding to the selected or target page. The calibration pass voltage controller 142 may receive the word line group information WL_GI from the word line determiner 141, set a calibration pass voltage level corresponding to the word line group information WL_GI, and output a calibration pass voltage generation control signal VPC_CS for controlling the voltage generator (e.g., 150 of FIG. 1) to generate a calibration pass voltage having the set calibration pass voltage level.

When the selected or target page is included in the first word line group 1st_GR of FIG. 5 during the program operation, the calibration pass voltage controller 142 may set the potential of the calibration pass voltage Vpass_cal to a first calibration pass voltage level Vpass_cal1 based on the word line group information WL_GI output from the word line determiner 141. The first calibration pass voltage level Vpass_cal1 may be lower than or equal to the potential of the pass voltage Vpass.

Also, when the selected or target page is included in the second word line group 2nd_GR of FIG. 5 during the program operation, the calibration pass voltage controller 142 may set the potential of the calibration pass voltage Vpass_cal to a second calibration pass voltage level Vpass_cal2 based on the word line group information WL_GI output from the word line determiner 141. The second calibration pass voltage level Vpass_cal2 may be lower than the first calibration pass voltage level Vpass_cal1.

Further, when the selected or target page is included in the third word line group 3rd_GR of FIG. 5 during the program operation, the calibration pass voltage controller 142 may set the potential of the calibration pass voltage Vpass_cal to a third calibration pass voltage level Vpass_cal3 based on the word line group information WL_GI output from the word line determiner 141. The third calibration pass voltage level Vpass_cal3 may be lower than the second calibration pass voltage level Vpass_cal2.

Furthermore, when the selected or target page is included in the fourth word line group 4th_GR of FIG. 5 during the program operation, the calibration pass voltage controller 142 may set the potential of the calibration pass voltage Vpass_cal to a fourth calibration pass voltage level Vpass_cal4 based on the word line group information WL_GI output from the word line determiner 141. The fourth calibration pass voltage level Vpass_cal4 may be lower than the third calibration pass voltage level Vpass_cal3.

At operation S850, the voltage generator 150 may generate a program voltage Vpgm, a pass voltage Vpass, and a calibration pass voltage Vpass_cal, and the address decoder 120 may apply the program voltage Vpgm, the pass voltage Vpass, and the calibration pass voltage Vpass_cal to the word lines WL1 to WLn.

The calibration pass voltage generator 153 of the voltage generator 150 may output the calibration pass voltage Vpass_cal by calibrating the potential level of the calibration pass voltage Vpass_cal in response to the calibration pass voltage generation control signal VPC_CS generated by the calibration pass voltage controller 142. For example, the calibration pass voltage generator 153 may generate and output the calibration pass voltage Vpass_cal having a calibration pass voltage level among the first calibration pass voltage level Vpass_cal1, the second calibration pass voltage level Vpass_cal2, the third calibration pass voltage level Vpass_cal3, and the fourth calibration pass voltage level Vpass_cal4, set by the calibration pass voltage controller 142, in response to the calibration pass voltage generation control signal VPC_CS.

The address decoder 120 may apply the program voltage Vpgm to a selected or target word line Sel WL among the word lines WL1 to WLn, apply the calibration pass voltage Vpass_cal to the lowermost word line WL0 among unselected or non-target word lines, and apply the pass voltage Vpass to the remaining unselected or non-target word lines Unsel WLs.

In an embodiment of the present disclosure, when the selected or target page is arranged farther away from the semiconductor substrate or the source select transistor, the calibration pass voltage Vpass_cal having a relatively low potential may be applied to the lowermost word line WL0. Due thereto, an electric field in the memory cells C0 connected to the lowermost word line WL0 may be decreased, and thus a program disturb phenomenon in which the threshold voltages of the memory cells C0 increase may be mitigated.

In the case where the calibration pass voltage Vpass_cal having a relatively low potential is applied to the lowermost word line WL0 when the selected or target page is arranged closer to the semiconductor substrate or the source select transistor, the potential level of channels of a plurality of memory cell strings corresponding to the selected or target page may not be sufficiently boosted, and thus the threshold voltages of some memory cells which are not to be programmed among the memory cells included in the selected or target page may increase. In an embodiment of the present disclosure, when the selected or target page is arranged closer to the semiconductor substrate or the source select transistor, the calibration pass voltage Vpass_cal having a relatively high potential may be applied to the lowermost word line WL0. As a result, by means of the calibration pass voltage Vpass_cal applied to the lowermost word line WL0, a channel boosting level may be increased to a certain level or more.

At operation S870, the control logic 140 may determine whether the selected or target page is the last page among pages on which the program operation is to be performed.

When it is determined at operation S870 that the selected or target page is not the last page among the pages on which the program operation is to be performed (in the case of “No”), the process may proceed to operation S890 of selecting a next page and re-performing a process starting from the above-described operation S830.

Furthermore, when it is determined at operation S870 that the selected or target page is the last page among the pages on which the program operation is to be performed (in the case of “Yes”), the program operation is terminated.

FIG. 11 is a block diagram illustrating a memory system including the semiconductor memory device of FIG. 1 according to an embodiment of the present disclosure.

Referring to FIG. 11, a memory system 1000 includes a semiconductor memory device 100 and a controller 1100.

The semiconductor memory device 100 may have the same configuration and operation as the semiconductor memory device described with reference to FIG. 1, and thus repetitive descriptions thereof will be omitted.

The controller 1100 may be connected to a host Host and the semiconductor memory device 100. The controller 1100 may access the semiconductor memory device 100 in response to a request from the host Host. For example, the controller 1100 may control read, write, erase, and background operations of the semiconductor memory device 100. The controller 1100 may provide an interface between the semiconductor memory device 100 and the host Host. The controller 1100 may run firmware for controlling the semiconductor memory device 100.

The controller 1100 includes a random access memory (RAM) 1110, a processing unit 1120, a host interface 1130, a memory interface 1140, and an error correction block 1150. The RAM 1110 may be used as at least one of a working memory for the processing unit 1120, a cache memory between the semiconductor memory device 100 and the host Host, and a buffer memory between the semiconductor memory device 100 and the host Host. The processing unit 1120 controls the overall operation of the controller 1100. In addition, the controller 1100 may temporarily store program data provided from the host Host during a write operation.

The host interface 1130 includes a protocol for performing data exchange between the host Host and the controller 1100. In an embodiment, the controller 1100 may communicate with the host Host through at least one of various communication interfaces or standards such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer system interface (SCSI) protocol, an enhanced small disk interface (ESDI) protocol, an integrated drive electronics (IDE) protocol, and a private protocol.

The memory interface 1140 interfaces with the semiconductor memory device 100. For example, the memory interface may include a NAND interface or NOR interface.

The error correction block 1150 may detect and correct errors in data received from the semiconductor memory device 100 using an error correction code (ECC). The processing unit 1120 may adjust a read voltage based on the result of error detection by the error correction block 1150, and may control the semiconductor memory device 100 to perform re-reading. In an embodiment, the error correction block may be provided as an element of the controller 1100.

The controller 1100 and the semiconductor memory device 100 may be integrated into a single semiconductor device. In an embodiment, the controller 1100 and the semiconductor memory device 100 may be integrated into a single semiconductor device to form a memory card. For example, the controller 1100 and the semiconductor memory device 50 may be integrated into a single semiconductor device to form a memory card such as a personal computer memory card international association (PCMCIA), a compact flash card (CF), a smart media card (SM or SMC), a memory stick, a multimedia card (MMC, RS-MMC, or MMCmicro), a SD card (SD, miniSD, microSD, or SDHC), or a universal flash storage (UFS).

The controller 1100 and the semiconductor memory device 100 may be integrated into a single semiconductor device to form a solid state drive (SSD). The SSD includes a storage device configured to store data in a semiconductor memory. When the memory system 1000 is used as the SSD, the operating speed of the host Host connected to the memory system 1000 may be remarkably improved.

In an embodiment, the memory system 1000 may be provided as one of various elements of an electronic device, such as a computer, an ultra-mobile PC (UMPC), a workstation, a net-book, a personal digital assistants (PDA), a portable computer, a web tablet, a wireless phone, a mobile phone, a smartphone, a wearable device, an e-book, a portable multimedia player (PMP), a game console, a navigation device, a black box, a digital camera, a three-dimensional (3D) television, a digital audio recorder, a digital audio player, a digital picture recorder, a digital picture player, a digital video recorder, a digital video player, a device capable of transmitting/receiving information in an wireless environment, one of various devices for forming a home network, one of various electronic devices constituting a computer network, one of various electronic devices constituting a telematics network, an RFID device, or one of various elements constituting a computing system.

In an embodiment, the semiconductor memory device 100 or the memory system 1000 may be mounted in various types of packages. For example, the semiconductor memory device 100 or the memory system 1000 may be packaged and mounted in a type such as package on package (PoP), ball grid arrays (BGAs), chip scale packages (CSPs), plastic leaded chip carrier (PLCC), plastic dual in line package (PDIP), die in waffle pack, die in wafer form, chip on board (COB), ceramic dual in line package (CERDIP), plastic metric quad flat pack (MQFP), thin quad flatpack (TQFP), small outline integrated circuit (SOIC), shrink small outline package (SSOP), thin small outline package (TSOP), system in package (SIP), multi-chip package (MCP), wafer-level fabricated package (WFP), or wafer-level processed stack package (WSP).

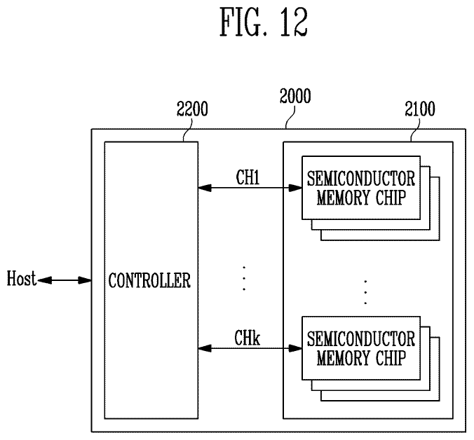

FIG. 12 is a block diagram illustrating an application of the memory system of FIG. 11 according to an embodiment of the present disclosure.

Referring to FIG. 12, a memory system 2000 includes a semiconductor memory device 2100 and a controller 2200. The semiconductor memory device 2100 may include a plurality of semiconductor memory chips. The semiconductor memory chips may be divided into a plurality of groups.

In FIG. 12, it is illustrated that the plurality of groups communicate with the controller 2200 through first to k-th channels CH1 to CHk, respectively. Each semiconductor memory chip may be configured and operated in the same manner as the semiconductor memory device 100 described with reference to FIG. 1.

Each group may communicate with the controller 2200 through one common channel. The controller 2200 has the same configuration as the controller 1100 described with reference to FIG. 12 and is configured to control the plurality of semiconductor memory chips of the semiconductor memory device 2100 through the plurality of channels CH1 to CHk.

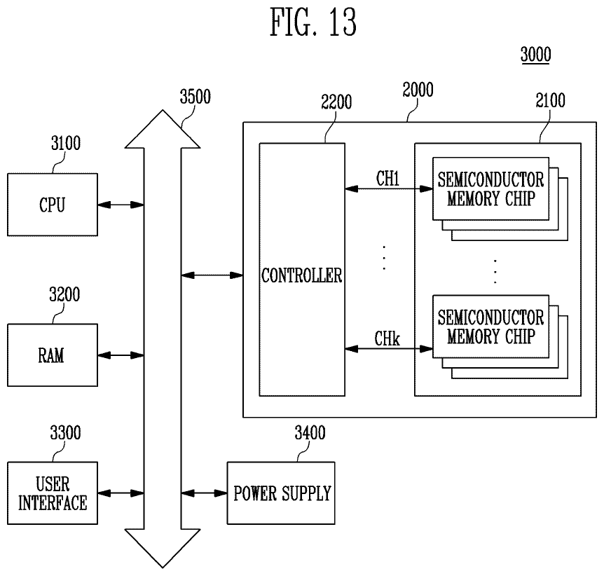

FIG. 13 is a block diagram illustrating a computing system including the memory system illustrated with reference to FIG. 12 according to an embodiment of the present disclosure.

Referring to FIG. 13, a computing system 3000 includes a central processing unit (CPU) 3100, a RAM 3200, a user interface 3300, a power supply 3400, a system bus 3500, and the memory system 2000.

The memory system 2000 is electrically connected to the CPU 3100, the RAM 3200, the user interface 3300, and the power supply 3400 through the system bus 3500. Data provided through the user interface 3300 or processed by the CPU 3100 may be stored in the memory system 2000.

In FIG. 13, the semiconductor memory device 2100 is illustrated as being connected to the system bus 3500 through the controller 2200. However, the semiconductor memory device 2100 may be directly connected to the system bus 3500. Here, the function of the controller 2200 may be performed by the CPU 3100 and the RAM 3200.

In FIG. 13, it is illustrated that the memory system 2000 described with reference to FIG. 12 is provided. However, the memory system 2000 may be replaced with the memory system 1000 described with reference to FIG. 11. In an embodiment, the computing system 3000 may include both of the memory systems 1000 and 2000 described with reference to FIGS. 11 and 12.

According to the embodiments of the present disclosure, during a program operation of a semiconductor memory device, a program disturb phenomenon on memory cells may be mitigated and a channel boosting level may be enhanced by calibrating a pass voltage applied to a memory cell arranged in a lowermost portion of a memory cell string based on the position of a selected or target page.

While the detailed embodiments of the present disclosure have been disclosed in the detailed description of the present disclosure, those skilled in the art will appreciate that various modifications, additions and substitutions are possible without departing from the scope and technical spirit of the present disclosure. Therefore, the scope of the present disclosure should not be limited to the foregoing embodiments, and should be defined by the appended claims and equivalents thereof. Furthermore, the embodiments may be combined to form additional embodiments.

What is claimed is:

1. A semiconductor memory device comprising:
a memory block including a plurality of pages;
a peripheral circuit configured to perform a program operation on the memory block by respectively applying a program voltage, a pass voltage, and a calibration pass voltage to a plurality of word lines respectively connected to the plurality of pages; and
a control logic configured to control the peripheral circuit to vary, during the program operation, a potential of the calibration pass voltage to be applied to a lowermost word line connected to a lowermost page, which is adjacent to a semiconductor substrate or a source select transistor among the plurality of pages, according to a position of a target page from among the plurality of pages.

2. The semiconductor memory device according to claim 1, wherein the control logic controls the peripheral circuit further to:
increase the potential of the calibration pass voltage as the target page is located closer to the semiconductor substrate or the source select transistor, and
decrease the potential of the calibration pass voltage as the target page is located farther from the semiconductor substrate or the source select transistor.

3. The semiconductor memory device according to claim 1, wherein:
the plurality of word lines are grouped into a plurality of word line groups,
the control logic controls the peripheral circuit further to generate, during the program operation on the target page, the calibration pass voltage having a selected one of different calibration pass voltage levels for the respective word line groups, and
the selected calibration pass voltage level corresponds to a target word line coupled to the target page and belonging to one of the word line groups.

4. The semiconductor memory device according to claim 3, wherein the control logic includes:
a word line determiner configured to determine the word line group including the target word line; and
a calibration pass voltage controller configured to output, according to a result of the determination, a calibration pass voltage generation control signal for controlling the peripheral circuit to generate the calibration pass voltage having the selected calibration pass voltage level.

5. The semiconductor memory device according to claim 4,
wherein the peripheral circuit comprises a voltage generator configured to generate the program voltage, the pass voltage, and the calibration pass voltage during the program operation, and
wherein the voltage generator generates, in response to the calibration pass voltage generation control signal, the calibration pass voltage having the selected calibration pass voltage level.

6. The semiconductor memory device according to claim 1, wherein the calibration pass voltage has a potential lower than or equal to a potential of the pass voltage.

7. The semiconductor memory device according to claim 1,
wherein the memory block includes a plurality of memory cells configuring the plurality of pages, and
wherein a width of a vertical channel layer of the memory cells included in the lowermost page is less than a width of a vertical channel layer of the memory cells included in remaining pages.

8. A semiconductor memory device comprising:
a memory block connected to a plurality of word lines grouped into a plurality of word line groups and including memory cells;
a voltage generator configured to generate, during a program operation on the memory block, a program voltage, a pass voltage, and a calibration pass voltage having a potential lower than or equal to a potential of the pass voltage;
an address decoder configured to, during the program operation:
apply the program voltage to a target word line among the plurality of word lines,
apply, among the plurality of word lines, the calibration pass voltage to a lowermost word line connected to lowermost memory cells adjacent to a semiconductor substrate or a source select transistor among the plurality of word lines, and
apply the pass voltage to remaining word lines other than the target word line and the lowermost word line among the plurality of word lines; and
a control logic configured to control the voltage generator to vary, during the program operation, the potential of the calibration pass voltage to be applied to the lowermost word line according to a target word line group including the target word line.

9. The semiconductor memory device according to claim 8, wherein the plurality of word line groups are arranged to be sequentially stacked on the semiconductor substrate.

10. The semiconductor memory device according to claim 8, wherein the control logic controls the voltage generator further to generate the calibration pass voltage having a selected one of different calibration pass voltage levels for the respective word line groups, the selected calibration pass voltage level corresponding to the target word line group.

11. The semiconductor memory device according to claim 10, wherein the control logic includes:
a word line determiner configured to determine the target word line group; and
a calibration pass voltage controller configured to output, according to a result of the determination, a calibration pass voltage generation control signal for controlling the voltage generator to generate the calibration pass voltage having the selected calibration pass voltage level.

12. The semiconductor memory device according to claim 8, wherein the lowermost memory cells have a channel layer, a width of which is less than a width of a channel layer of the memory cells connected to remaining word lines among the plurality of word lines.

13. A semiconductor memory device comprising:
a memory block including memory cells connected to a plurality of word lines;
a peripheral circuit configured to apply a program voltage to a target word line and apply a pass voltage and a calibration pass voltage to non-target word lines, among the plurality of word lines during a program operation on the memory block; and
a control logic configured to control the peripheral circuit to sequentially decrease, during the program operation, a potential of the calibration pass voltage to be applied to one of the non-target word lines as a distance between the target word line and a lowermost word line, to which the calibration pass voltage is applied among the non-target word lines, becomes longer.

14. The semiconductor memory device according to claim 13, wherein the lowermost word line is located closer to a semiconductor substrate or a source select transistor.

15. The semiconductor memory device according to claim 13, wherein the potential of the calibration pass voltage is lower than a potential of the pass voltage.

16. The semiconductor memory device according to claim 13, wherein the peripheral circuit includes:
a pass voltage generator configured to generate the pass voltage; and
a calibration pass voltage generator configured to generate the calibration pass voltage.

17. The semiconductor memory device according to claim 13, wherein:
the plurality of word lines are grouped into at least four word line groups, and
the potential of the calibration pass voltage is different for the individual word line groups.

18. The semiconductor memory device according to claim 17, wherein the potential of the calibration pass voltage is lower than a potential of the pass voltage except in a case where the target word line and the lowermost word line belong to an identical word line group among the word line groups.
